(19) United States
(12) Patent Application Publication
(10) Pub. No.: US 2023/0067595 A1
(43) Pub. Date: Mar. 2, 2023

(54) PACKAGE STRUCTURE WITH ANTENNA CIRCUIT

(71) Applicant: Jabil Circuit (Singapore) Pte. Ltd., Singapore (SG)

(72) Inventors: Chi-Neng Ho, Taichung City (TW); Sheng-Wen Ni, Taichung City (TW); Yu-Cheng Lin, Taichung City (TW); Yen-Chou Chen, Taichung City (TW)

(73) Assignee: Jabil Circuit (Singapore) Pte. Ltd., Singapore (SG)

(21) Appl. No.: 17/897,635

(22) Filed: Aug. 29, 2022

(30) Foreign Application Priority Data
Sep. 2, 2021 (TW) 110210356

(51) Int. Cl. H05K 1/02; H05K 1/11; H01Q 9/04; H01Q 1/22

(52) U.S. Cl. CPC H05K 1/0243; H05K 1/0277; H05K 1/11; H01Q 9/0407; H01Q 1/22; H05K 2201/10098

(57) ABSTRACT

A package structure includes a carrier substrate, a circuit unit, and a packaging unit. The circuit unit includes an antenna circuit, and a conducting circuit that is flexible and that is electrically connected to the antenna circuit. At least a portion of the antenna circuit is disposed on the carrier substrate. The packaging unit is disposed on the carrier substrate by molding and encapsulates the circuit unit such that a portion of the circuit unit is exposed to permit said conducting circuit for electrical connection with the outside.

### CROSS-REFERENCE TO RELATED APPLICATION

This application claims priority of Taiwanese Invention Patent Application No. 110210356, filed on Sep. 2, 2021.

### FIELD

The disclosure relates to a package structure, and more particularly to a package structure with antenna circuit.

### BACKGROUND

Antenna circuits are widely used in the wireless communication industry because they can be used to receive/transmit electromagnetic waves or to generate radiated electromagnetic fields by applying current.

Taking for example an antenna element for a vehicle, an antenna circuit pattern is attached to a surface of a carrier plate. The carrier plate is usually made by injection molding, and has different structural forms or surface appearances according to the different disposition requirements. Further, usually a plurality of bosses are formed on the carrier plate for supporting or connecting, thereby affecting the adhesion between the antenna circuit pattern and the surface of the carrier plate, resulting in the antenna circuit pattern being easily removed or damaged in the subsequent packaging process.

### SUMMARY

Therefore, an object of the present disclosure is to provide a package structure having an antenna circuit that can alleviate at least one of the drawbacks of the prior art.

According to one aspect of this disclosure, a package structure includes a carrier substrate that is insulating and flexible, a circuit unit, and a packaging unit. The circuit unit includes an antenna circuit, and a conducting circuit that is flexible and that is electrically connected to the antenna circuit. At least a portion of the antenna circuit is disposed on the carrier substrate. The packaging unit is disposed on the carrier substrate by molding and encapsulates the circuit unit such that a portion of the circuit unit is exposed to permit the conducting circuit for electrical connection with the outside.

Another object of the present disclosure is to provide a package structure having an antenna circuit that can alleviate at least one of the drawbacks of the prior art.

According to another aspect of this disclosure, a package structure includes a carrier substrate that is insulating and flexible, a circuit unit, and a packaging unit. The circuit unit includes an antenna circuit, a conducting circuit that is flexible and that is electrically connected to the antenna circuit, a printed circuit board that is flexible, and a conductive adhesive member. The antenna circuit is disposed on the carrier substrate. The conducting circuit is formed on the printed circuit board. The conductive adhesive member is formed on a portion of a surface of the antenna circuit for connecting the antenna circuit to the conducting circuit. The packaging unit is disposed on the carrier substrate by molding and encapsulates the circuit unit such that the conducting circuit is partially exposed for electrical connection with the outside.

Still another object of the present disclosure is to provide a package structure having an antenna circuit that can alleviate at least one of the drawbacks of the prior art.

According to another aspect of this disclosure, a packaging structure includes a carrier substrate that is insulating and flexible, a circuit unit, and a packaging unit. The circuit unit includes a printed circuit board that is flexible, an antenna circuit, and a conducting circuit electrically connected to the antenna circuit. The printed circuit board is partially connected to the carrier substrate and has one side that is bent. The antenna circuit is at least partially formed on the printed circuit board in a range where the printed circuit board is connected to the carrier substrate. The conducting circuit is formed on the printed circuit board at the one side that is bent. The packaging unit is disposed on the carrier substrate by molding and encapsulates the circuit unit such that the one side of the printed circuit board that is bent and a portion of the circuit unit are exposed to permit the conducting circuit for electrical connection with the outside.

### BRIEF DESCRIPTION OF THE DRAWINGS

Other features and advantages of the disclosure will become apparent in the following detailed description of the embodiments with reference to the accompanying drawings, of which:

FIG. 1 is a side schematic view of a package structure according to the first embodiment of the present disclosure;

FIG. 2 is a side schematic view of a package structure according to the second embodiment of the present disclosure;

FIG. 3 is a fragmentary partly enlarged view of FIG. 2; and

FIG. 4 illustrates an alternative form of the second embodiment.

### DETAILED DESCRIPTION

Before the present disclosure is described in greater detail with reference to the accompanying embodiments, it should be noted herein that like elements are denoted by the same reference numerals throughout the disclosure.

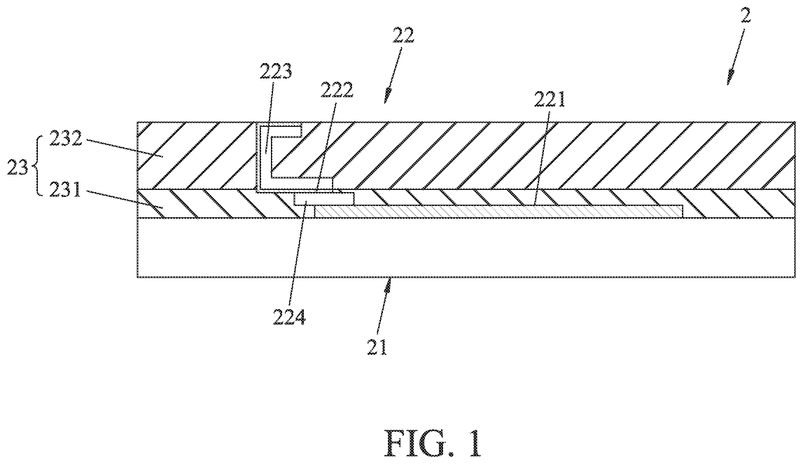

Referring to FIG. 1, a package structure 2 according to the first embodiment of the present disclosure includes a carrier substrate 21, a circuit unit 22, and a packaging unit 23.

The carrier substrate 21 is insulating and flexible, and can be used for connecting with electronic components configured in different structural forms. In this embodiment, the carrier substrate 21 is a thin film selected from the group consisting of plastic (e.g. PET) and rubber.

The circuit unit 22 includes an antenna circuit 221, a conducting circuit 222, a printed circuit board 223 that is flexible, and a conductive adhesive member 224. In this embodiment, the antenna circuit 221 is horizontally disposed on the carrier substrate 21, and is an antenna pattern made of a conductive material. Specifically, the antenna circuit 221 is made of conductive silver paste, and is formed on the carrier substrate 21 by printing. The conducting circuit 222 is flexible, and is formed on the printed circuit board 223. One side of the printed circuit board 223 is connected to the antenna circuit 221 through the conductive adhesive member 224 so as to electrically connect the conducting circuit 222 and the antenna circuit 221 to each other. Specifically, the conductive adhesive member 224 is formed on a portion of a surface of the antenna circuit 221 for connecting the conducting circuit 222 to the antenna circuit 221. In this embodiment, the conductive adhesive member 224 is made of an anisotropic conductive film (ACF).

Another side of the printed circuit board 223 opposite to the antenna circuit 221 is bent at an angle relative to the carrier substrate 21 so as to be conducive to electrical connection with the outside after subsequent encapsulation. It should be noted herein that the printed circuit board 223 may be extended or bent in different forms depending on the structural requirements of subsequent packaging components, as long as the conducting circuit 222 can be partially exposed from the packaging unit 23.

The packaging unit 23 is disposed on the carrier substrate 21 by molding, and encapsulates the circuit unit 22 such that a portion of the circuit unit 22 is exposed to permit the conducting circuit 222 for electrical connection with the outside. The packaging unit 23 is made of an insulating material selected from the group consisting of resin, primer and silicone, and can have a single layer structure or a multilayer structure. In this embodiment, the packaging unit 23 is exemplified as including an interface layer 231 and an encapsulating layer 232.

The interface layer 231 is made from primer, is formed on the carrier substrate 21, and encapsulates at least the antenna circuit 221. The encapsulating layer 232 is made from resin, is formed on the interface layer 231, and covers the conducting circuit 222 and the printed circuit board 223 such that one end of the conducting circuit 222 opposite to the antenna circuit 221 is exposed to the outside. The interlace layer 231 is made of a material different from that of the encapsulating layer 232 to increase connection between the carrier substrate 21 and the encapsulating layer 232.

With the packaging unit 23 encapsulating the circuit unit 22, the antenna circuit 221 can be tightly adhered to the carrier substrate 21 so as to stabilize the conducting circuit 222 and prevent the same from being damaged or removed, and the adhesion between the carrier substrate 21 and the encapsulating layer 232 can be increased through the interface layer 231. It should be noted herein that the packaging unit 23 may only be composed of a single or multiple layers of insulating material depending on the requirements or the material of the carrier substrate 21, so that the number of layers thereof does not need to be particularly limited.

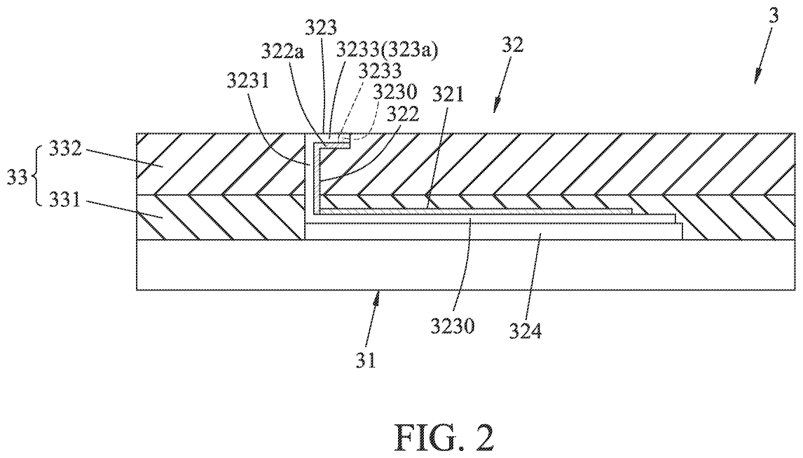

Referring to FIG. 2, a package structure 3 according to the second embodiment of the present disclosure includes a carrier substrate 31, a circuit unit 32, and a packaging unit 33. Since the structure and materials of the carrier substrate 31 similar to that of the carrier substrate 21 described in the first embodiment, a detailed description thereof will be omitted herein for the sake of brevity. The packaging unit 33 also includes an interface layer 331 formed on the carrier substrate 31 and an encapsulating layer 332.

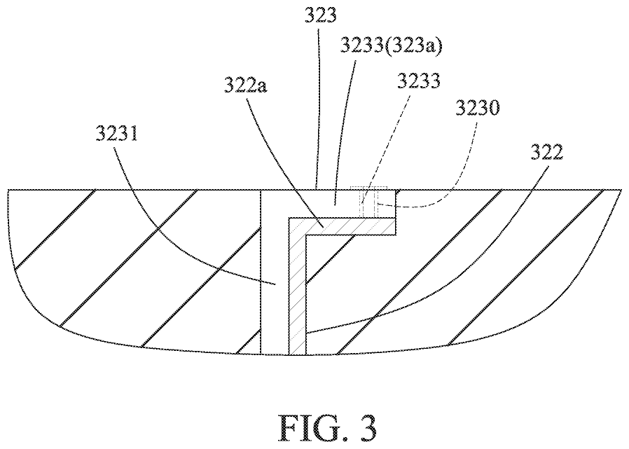

In this embodiment, the circuit unit 32 includes an antenna circuit 321, a conducting circuit 322 that is flexible, a printed circuit board 323 that is flexible, and an adhesive member 324. As shown in FIGS. 2 and 3, the circuit unit 32 further includes a first section 322a and a second section 323a that is exposed from the encapsulating layer 332 to permit the first section 322a for electrical connection with the outside. Specifically, in this embodiment, the second section 323a is formed with a through via 3230 that is exposed to the outside and that includes a conducting pad 3233 connected to the first section 323a so the first section 322a is electrically exposed to the outside. In other embodiments, a wire may be provided to extend through the second section 323a and connected to the first section 322a to permit the first section 322a for electrical connection with the outside.

In this embodiment, the printed circuit board 323 has a main portion 3230 connected to the carrier substrate 31 through the adhesive member 324, a first bent portion 3231 bent at an angle relative to the main portion 3230, and a second bent portion 3232 that is bent at an angle relative to the first bent portion 3231, that is opposite to the carrier substrate 31, and that is exposed from the packaging unit 33 for electrical connection with the outside. It should be noted herein that the printed circuit board 323 may be extended or bent in different forms depending on the requirements or the relative positions of electronic components to be disposed thereto, as long as the second bent portion 3232 of the printed circuit board 323 can be exposed from the packaging unit 33.

The antenna circuit 321 is formed on the main portion 3230 of the printed circuit board 323 at a side opposite to the carrier substrate 31 and in a range where the printed circuit board 323 is adhered to the carrier substrate 31. The conducting circuit 322 is formed on the first and second bent portions 3231, 3232 of the printed circuit board 323, and is electrically connected to the antenna circuit 321. Preferably, the antenna circuit 321 is horizontally disposed on the carrier substrate 31 to prevent bending thereof and to have a long radiation length.

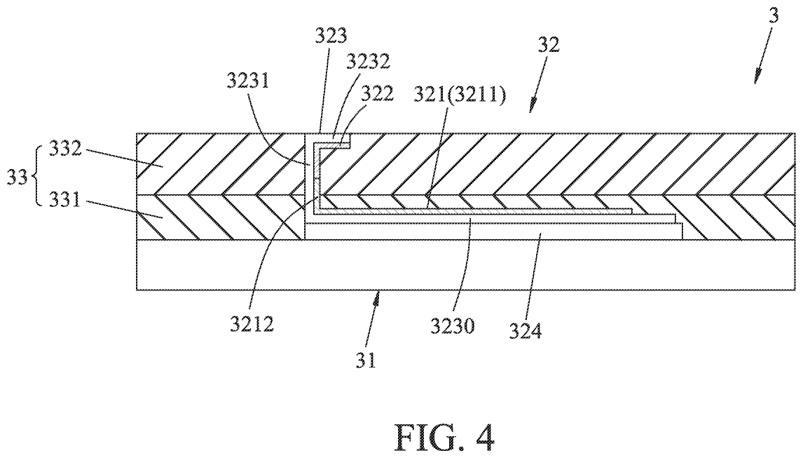

FIG. 4 illustrates an alternative form of the second embodiment, in which the antenna circuit 321 has a main antenna circuit portion 3211 connected to the main portion 3230 of the carrier substrate 31 and in the range where the printed circuit board 323 is adhered to the carrier substrate 31, and a remaining antenna circuit portion 3212 extending transversely from the main antenna circuit portion 3211 and formed on the first bent portion 3231 of the printed circuit board 323 and electrically connected to the conducting circuit 322.

In summary, in the package structure 2, 3 of this disclosure, the antenna circuit 221, 321 is formed on the flexible carrier substrate 21 or the flexible printed circuit board 323, and is electrically connected with the outside only through a portion of the conducting circuit 222 or the second bent portion 3232 of the printed circuit board 323, which is beneficial for the disclosure to be disposed on components with different forms in subsequent applications. Furthermore, the packaging unit 23, 33 formed by molding is used to encapsulate the circuit unit 22, 32 so as to prevent the antenna circuit 221, 321 and the conducting circuit 222, 322 from being damaged or removed. Therefore, the object of this disclosure can indeed be achieved.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A package structure comprising:
a carrier substrate that is insulating and flexible;
a circuit unit including an antenna circuit, and a conducting circuit that is flexible and that is electrically connected to said antenna circuit, at least a portion of said antenna circuit being disposed on said carrier substrate; and
a packaging unit disposed on said carrier substrate by molding and encapsulating said circuit unit such that a portion of said circuit unit is exposed to permit said conducting circuit for electrical connection with the outside.

2. The package structure as claimed in claim 1, wherein said antenna circuit is made of conductive silver paste, said circuit unit further including a printed circuit board that is flexible, said conducting circuit being formed on said printed circuit board, one side of said printed circuit board being connected to said antenna circuit such that said antenna circuit and said conducting circuit are electrically connected to each other.

3. The package structure as claimed in claim 2, wherein said circuit unit further includes a conductive adhesive member formed on a portion of a surface of said antenna circuit for connecting said conducting circuit to said antenna circuit, said conductive adhesive member being made of an anisotropic conductive film (ACF).

4. The package structure as claimed in claim 1, wherein said circuit unit further includes a printed circuit board that is flexible, said antenna circuit being formed on said printed circuit board, said printed circuit board being partially connected to said carrier substrate and having one side that is bent and that is exposed from said packaging unit, said conducting circuit being formed on said printed circuit board at said one side that is bent, and being electrically connected to said antenna circuit.

5. The package structure as claimed in claim 4, wherein said circuit unit further includes an adhesive layer for connecting and adhering at least a portion of said printed circuit board formed with said antenna circuit to said carrier substrate.

6. The package structure as claimed in claim 1, wherein said antenna circuit has a main antenna circuit portion connected to said carrier substrate.

7. The package structure as claimed in claim 1, wherein said antenna circuit is horizontally disposed on said carrier substrate.

8. The package structure as claimed in claim 1, wherein said packaging unit is made of an insulating material, and includes an interface layer formed on said carrier substrate and encapsulating at least said antenna circuit, and an encapsulating layer formed on said interface layer and covering at least said conducting circuit such that one end of said conducting circuit opposite to said antenna circuit is exposed, and wherein said interface layer is made of a material different from that of said encapsulating layer to increase connection between said carrier substrate and said encapsulating layer.

9. The package structure as claimed in claim 8, wherein said portion of said circuit unit includes a first section and a second section that is exposed from said encapsulating layer to permit said first section for electrical connection with the outside.

10. The package structure as claimed in claim 9, wherein said second section is formed with a through via exposed to the outside and connected to said first section to permit said first section for electrical connection with the outside.

11. A package structure comprising:
a carrier substrate that is insulating and flexible;
a circuit unit including an antenna circuit, a conducting circuit that is flexible and that is electrically connected to said antenna circuit, a printed circuit board that is flexible, and a conductive adhesive member, wherein said antenna circuit is disposed on said carrier substrate, said conducting circuit is formed on said printed circuit board, and said conductive adhesive member is formed on a portion of a surface of said antenna circuit for connecting said antenna circuit to said conducting circuit; and
a packaging unit disposed on said carrier substrate by molding and encapsulating said circuit unit such that said conducting circuit is partially exposed for electrical connection with the outside.

12. A package structure comprising:
a carrier substrate that is insulating and flexible;
a circuit unit including a printed circuit board that is flexible, an antenna circuit, and a conducting circuit electrically connected to said antenna circuit, said printed circuit board being partially connected to said carrier substrate and having one side that is bent, said antenna circuit being at least partially formed on said printed circuit board in a range where said printed circuit board is connected to said carrier substrate, said conducting circuit being formed on said printed circuit board at said one side that is bent; and
a packaging unit disposed on said carrier substrate by molding and encapsulating said circuit unit such that said one side of said printed circuit board that is bent and a portion of said circuit unit are exposed to permit said conducting circuit for electrical connection with the outside.
